(19) United States
(12) Patent Application Publication
(10) Pub. No.: US 2009/0268395 A1
(43) Pub. Date: Oct. 29, 2009

(54) Backplate for heat radiator

(75) Inventor: Chun-Tsang Chen, Sinjhuang City (TW)

Correspondence Address: NIKOLAI & MERSEREAU, P.A., 900 SECOND AVENUE SOUTH, SUITE 820, MINNEAPOLIS, MN, 55402, US

(73) Assignee: Asia Vital Components Co., Ltd., Sinjhuang City (TW)

(21) Appl. No.: 12/288,521

(22) Filed: Oct. 21, 2008

(30) Foreign Application Priority Data
Apr. 25, 2008 (TW) 097207194

(51) Int. Cl. H05K 7/20

(52) U.S. Cl. 361/679.54

(57) ABSTRACT

A backplate for heat radiator is configured to mount to a rear side of a motherboard, and is provided at predetermined positions with an insulating bonding material. The insulating bonding material not only firmly connects the backplate to the rear side of the motherboard, but also serves as an insulating means between the metal backplate and the motherboard. That is, with the insulating bonding material, the backplate would not separate from the motherboard when the motherboard is moved, and the motherboard is electrically insulated from the backplate.

### FIELD OF THE INVENTION

The present invention relates to a backplate for heat radiator, and more particularly to a backplate for heat radiator that may be attached to a rear side of a motherboard to give the motherboard an increased structural strength.

### BACKGROUND OF THE INVENTION

With the highly developed semiconductor technology, the currently available integrated circuits (ICs) have a largely reduced volume than before. To enable the ICs to process more data, the number of elements and components included in the current ICs is often several times of that in the conventional ICs having the same volume. However, heat produced by the ICs during operation thereof increases with the growing number of electronic elements and components in the ICs. For example, the heat produced by a common central processing unit (CPU) at full working load is high enough for burning out the whole CPU. Therefore, it is important to develop effective heat radiating means for the ICs.

One solution for dissipating the heat produced by the CPU is to provide on the CPU with a heat radiating unit, such as a heat radiator, so that the heat produced by the CPU may be quickly radiated. The heat radiating unit is usually fastened to the motherboard. However, the motherboard is made of a printed circuit board (PCB), which has a relatively low strength and tends to bend and deform at areas to which the heat radiating unit is fastened. In a worse condition, the motherboard would even break due to vibration and other unpredictable external forces.

Taiwan Patent Publication No. 200717217 discloses a backplate assembly as shown in FIG. 1. The backplate assembly includes a backplate 11 for bearing against a lower surface of a motherboard 2, a plurality of fastening elements 13 attached to the backplate 11 for upward extending through the motherboard 2, and a plurality of elastic retaining elements 14 for engaging with the fastening elements 13 extended through the motherboard 2 so as to bear against an upper surface of the motherboard 2. That is, the backplate 11 is fixed below the motherboard 2 via the fastening elements 13 and the elastic retaining elements 14. This structure is not ideal in practical use thereof because additional fastening elements 13 and elastic retaining elements 14 are required to fixedly mount the backplate 11 to the motherboard 2 and a flat insulating member 12 must be provided between the backplate 11 and the motherboard 2 to electrically insulate the motherboard 2 from the backplate 11.

In brief, the conventional backplate for heat radiator has the following disadvantages: (1) having complicated structure, (2) requiring time and labor to assemble, and (3) requiring high manufacturing cost.

It is therefore tried by the inventor to develop an improved backplate for heat radiator to eliminate the disadvantages in the prior art.

### SUMMARY OF THE INVENTION

A primary object of the present invention is to provide a backplate for heat radiator that can be directly bonded to a motherboard without the risk of separating from the motherboard when the latter is moved.

Another object of the present invention is to provide a backplate for heat radiator that can be connected to a motherboard to increase the structural strength of the motherboard while being electrically insulated from the motherboard.

To achieve the above and other objects, the backplate for heat radiator according to of the present invention is configured to mount to a rear side of a motherboard. For this purpose, the backplate is provided at predetermined positions with an insulating bonding material, via which the backplate is bonded to the motherboard without the risk of separating from the motherboard when the latter is moved. Meanwhile, the bonding material provides an insulating effect between the backplate and the motherboard.

Therefore, the backplate for heat radiator according to the present invention has the following advantages: (1) having simple structure, (2) being easy to assemble to a motherboard, and (3) requiring only low manufacturing cost.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of a conventional backplate for heat radiator;

FIG. 2 is an exploded perspective view of a backplate for heat radiator according to a first preferred embodiment of the present invention;

FIG. 3 is an assembled sectional view of FIG. 2;

FIG. 4 is an assembled perspective view of a backplate for heat radiator according to a second embodiment of the present invention;

FIG. 5 is an assembled sectional view of FIG. 4;

FIG. 6 is an assembled perspective view of a backplate for heat radiator according to a third embodiment of the present invention; and

FIG. 7 is an assembled sectional view of FIG. 6.

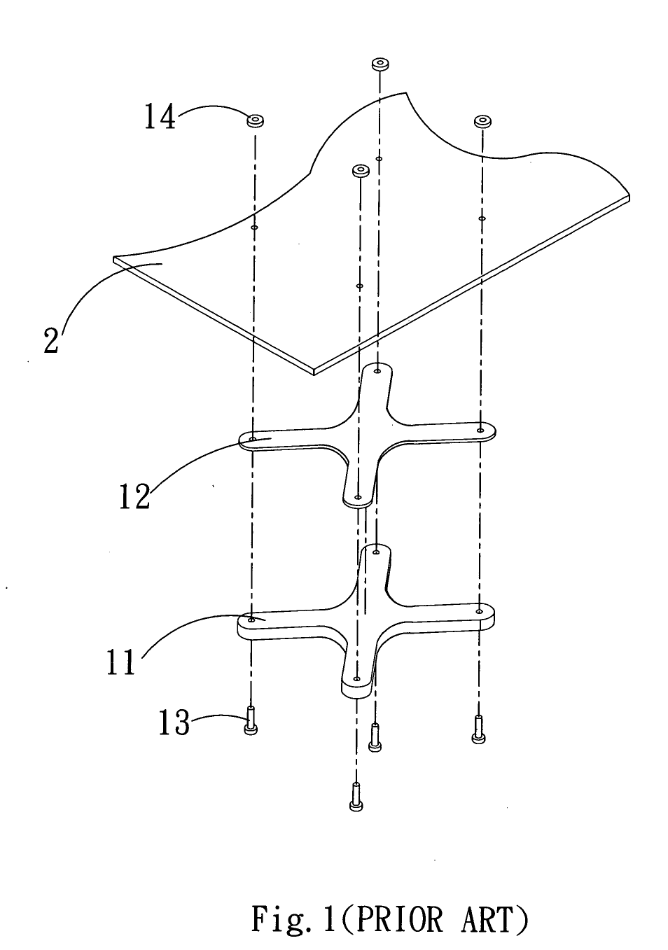

### DETAILED DESCRIPTION OF THE PREFERRED EMBODIMENTS

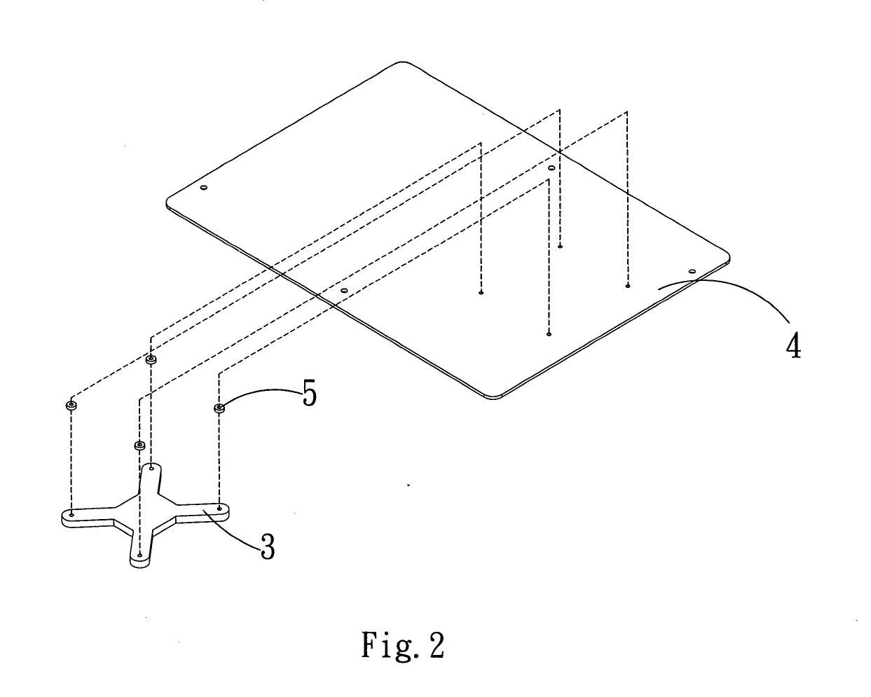

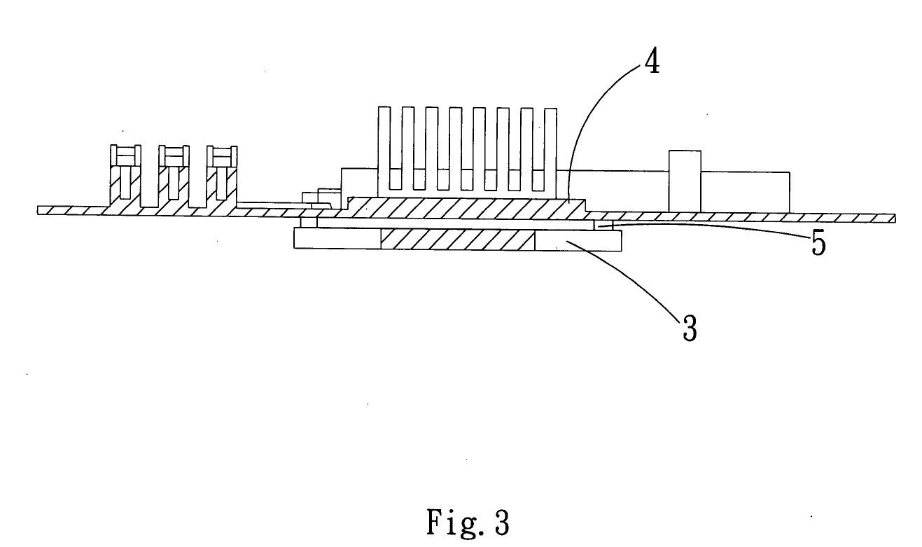

Please refer to FIGS. 2 and 3, which are exploded perspective view and assembled sectional view, respectively, of a backplate for heat radiator according to a first preferred embodiment of the present invention. As shown, the backplate, which is denoted a reference numeral 3, is for mounting to a rear side of a motherboard 4. The backplate 3 is provided at predetermined positions with an insulating bonding material 5. Generally, the backplate 3 is made of a metal material. When the backplate 3 is mounted to the rear side of the motherboard 4, the insulating bonding material 5 not only firmly connects the backplate 3 to the rear side of the motherboard 4, but also serves as an insulating means between the metal backplate 3 and the motherboard 4 to prevent the backplate 3 from touching circuits (not shown) provided on the rear side of the motherboard 4 to thereby avoid the occurrence of short circuit. That is, with the insulating bonding material 5, the backplate 3 would not separate from the motherboard 4 when the motherboard is moved, and the motherboard 4 is electrically insulated from the backplate 3. Therefore, the additional fastening elements and elastic retaining elements, as well as the flat insulating member used in the conventional backplate are saved in the present invention, enabling the backplate to have a simplified structure and be easily assembled to the motherboard in an insulated manner.

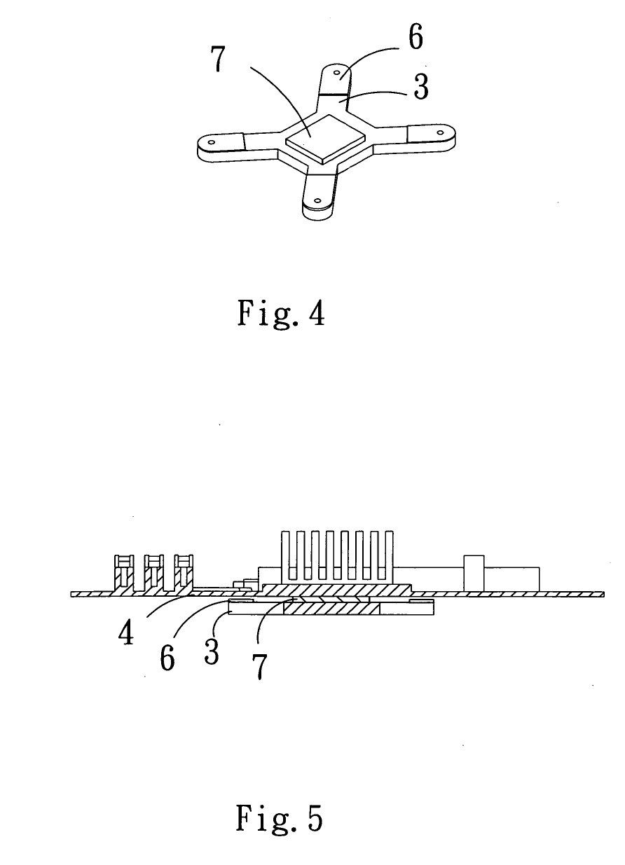

Please refer to FIGS. 4 and 5 that are assembled perspective and sectional views, respectively, of a backplate for heat radiator according to a second embodiment of the present invention. As shown, in the second embodiment, the backplate 3 is provided on one surface at predetermined positions with an insulating material 6, and on the same surface at a central area with a bonding material 7. It is noted the insulating material 6 is provided on the backplate 3 only at localized areas. When the backplate 3 is mounted to the rear side of the motherboard 4, the bonding material 7 firmly bonds the backplate 3 to the motherboard 4 while the insulating material 6 localized on the backplate 3 prevents the backplate 3 from contacting with the motherboard 4 to cause short circuit on the motherboard 4.

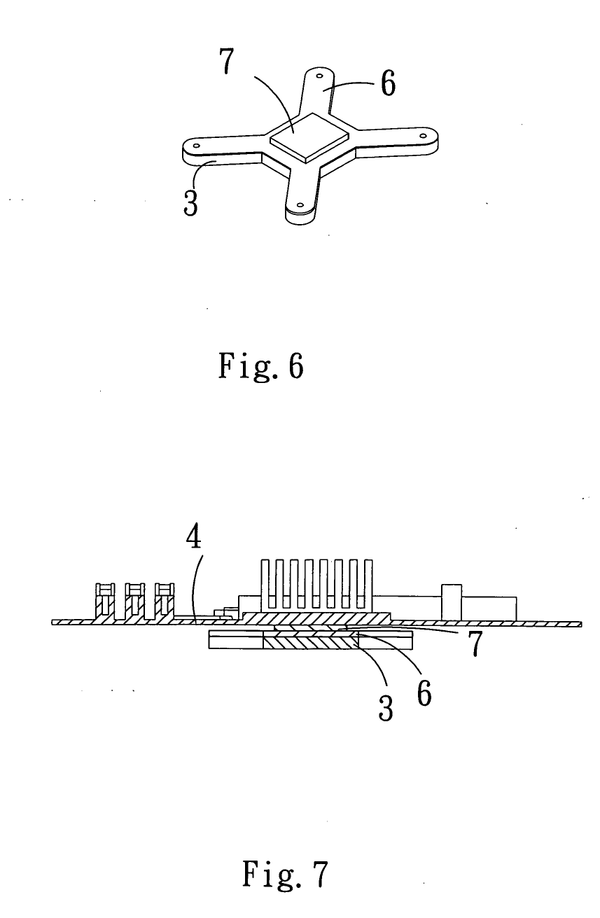

FIGS. 6 and 7 are assembled perspective and sectional views, respectively, of a backplate for heat radiator according to a third embodiment of the present invention. As shown, in the third embodiment, the backplate 3 is provided on one surface with a layer of insulating material 6, and on the layer of insulating material at a predetermined position with a bonding material 7. With the layer of insulating material 6, short circuit on the motherboard 4 caused by contacting with the metal backplate 3 can be avoided. And, with the bonding material 7, the backplate 3 may be firmly attached to the rear side of the motherboard 4.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A backplate for heat radiator configured to mount to a rear side of a motherboard, comprising a backplate being provided at predetermined positions with at least one insulating bonding material, via which the backplate is directly attached to the rear side of the motherboard without the risk of separating from the motherboard when the latter is moved, and the insulating bonding material also enabling the motherboard to be electrically insulated from the backplate.

2. A backplate for heat radiator configured to mount to a rear side of a motherboard, comprising a backplate being provided at predetermined positions with at least one insulating material and at least one bonding material, such that the backplate is directly mounted to the rear side of the motherboard by the bonding material without the risk of separating from the motherboard when the latter is moved, and the motherboard is electrically insulated from the backplate by the insulating material.

3. The backplate for heat radiator as claimed in claim 2, wherein a layer of the insulating material is first provided on one surface of the backplate, and the bonding material is then provided on the layer of insulating material at a predetermined position.

4. The backplate for heat radiator as claimed in claim 2, wherein the insulating material is provided on one surface of the backplate at predetermined localized areas, and the bonding material is provided on the same surface of the backplate at a predetermined position without contacting with the insulating material.
